(19) United States
(12) Patent Application Publication
(10) Pub. No.: US 2026/0040887 A1
(43) Pub. Date: Feb. 5, 2026

(54) DICING TAPE AND METHOD OF MANUFACTURING SEMICONDUCTOR DEVICES

(71) Applicant: TEXAS INSTRUMENTS INCORPORATED, DALLAS, TX (US)

(72) Inventors: RONGWEI ZHANG, Plano, TX (US); MICHAEL TODD WYANT, Dallas, TX (US); DANNY L. BRIJA, Allen, TX (US)

(21) Appl. No.: 18/791,016

(22) Filed: Jul. 31, 2024

(51) Int. Cl. H01L 21/683; H01L 21/3065; H01L 21/56; H01L 21/78; H01L 23/00

(52) U.S. Cl. CPC H01L 21/6836; H01L 21/78; H01L 21/3065; H01L 21/56; H01L 24/92; H01L 2224/92247

(57) ABSTRACT

A method of forming an integrated circuit (IC) is provided. The method includes applying a die attach film to a first surface of a wafer opposite a second surface. The method also includes applying a passivation layer to the second surface of the wafer. The method further includes patterning the passivation layer to define a number of scribe lines. The method yet further includes applying a dicing tape having a nonconductive material to the die attach film. The nonconductive material is resistant to plasma etching. The method includes plasma etching the wafer to form dies of a plurality of dies supported by the dicing tape based on the scribe lines.

### TECHNICAL FIELD

This description relates to a method of manufacturing semiconductor devices using a dicing tape that is resistant to plasma etching.

### BACKGROUND

Semiconductor devices are fabricated on substrates. For example, the substrate is a wafer having numerous devices (e.g., dies, chips, etc.). After fabrication on the substrate, the individual devices are singulated from each other using a dicing technique. However, the dicing techniques suffer from limitations that increase costs and material losses. For example, mechanical dicing techniques rely on blades to saw the substrate. Accordingly, the number of dies that the substrate yields is at least partially based on the width of the blades. Moreover, the substrate may be chipped or cracked during singulation due to the force exerted by the blade on the wafer. Similarly, laser dicing techniques can cause splintering of the substrate as a result of expansion during singulation.

### SUMMARY

In one example, a method of forming an integrated circuit (IC) is provided. The method includes applying a die attach film to a first surface of a wafer opposite a second surface. The method also includes applying a passivation layer to the second surface of the wafer. The method further includes patterning the passivation layer to define a number of scribe lines. The method yet further includes applying a dicing tape having a nonconductive material to the die attach film. The nonconductive material is resistant to plasma etching. The method includes plasma etching the wafer to form dies of a plurality of dies supported by the dicing tape based on the scribe lines.

Another example relates to another method of forming an IC. The method includes forming a die attach film to a first surface of a wafer opposite a second surface. The method also includes applying a passivation layer to the second surface of the wafer. The method yet further includes patterning the passivation layer to define a number of scribe lines. The method includes applying a dicing tape having a nonconductive material to the die attach film. The nonconductive material is resistant to plasma etching. The method also includes plasma etching the wafer to form dies of a plurality of dies supported by the dicing tape based on the scribe lines. The method yet further includes mounting the die to an interconnect by the die attach film. The method includes affixing a bond wire from the die to the interconnect. The method also includes encapsulating the die, the bond wire, and the interconnect in a mold compound.

In yet another example, a dicing tape for semiconductor manufacturing is provided. The dicing tape includes a filler material and a nonconductive material. The nonconductive material is silicon dioxide and is resistant to plasma etching. The silicon dioxide has a particle size of 1 nanometer to 10 micrometers based on a thickness of the dicing tape.

### BRIEF DESCRIPTION OF THE DRAWINGS

FIG. 1 is a cross-sectional view of a substrate affixed to a dicing tape, according to one example.

FIG. 2 is a cross-sectional view of a non-conductive material combined with a filler material of a dicing tape, according to one example.

FIG. 3 is a cross-sectional view of a substrate affixed to a dicing tape having an etch stop layer, according to another example.

FIGS. 4-15 illustrate stages of an example process flow for forming a semiconductor device.

FIG. 16 illustrates an example integrated circuit package fabricated using the dicing tape.

FIG. 17 illustrates a flowchart of an example method for fabricating semiconductor device.

### DETAILED DESCRIPTION

In semiconductor industries, demands for miniaturization have accelerated the development of smaller integrated devices. However, dicing techniques suffer from limitations at the smaller sizes. Mechanical dicing and laser dicing techniques can cause chipping, splintering, and breakage along the die edges. Furthermore, the limitations of these dicing techniques are exacerbated as substrates become thinner. In addition to becoming thinner, the area of semiconductor devices is decreasing. However, the area consumed by the saw blade during mechanical dicing may be greater than 100 microns. For wafers containing small dies (e.g., individual semiconductor devices with a die size of 500 microns×500 microns and smaller) this can represent a loss of greater than 20%.

Plasma dicing techniques are a non-mechanical alternative to mechanical dicing techniques. Rather than relying on a blade, plasma dicing uses high-energy plasma formed from gases, such as SF₆ and C₄F₈, to etch the substrate. However, plasma dicing techniques can sever the dicing tape that secures the singulated dies, causing the singulated dies to scatter. A dicing tape and method of manufacturing semiconductor devices are described. The dicing tape includes a nonconductive material that acts as an etch stop. For example, the nonconductive material is silicon dioxide that is resistant to plasma dicing. Accordingly, the nonconductive material prevents the dicing tape from being severed during singulation. As one example, the dicing tape has a single structure, and the nonconductive material is incorporated with a filler material of the dicing tape. As another example, the dicing tape has a multilayer structure including a base layer and an etch stop layer having the nonconductive material.

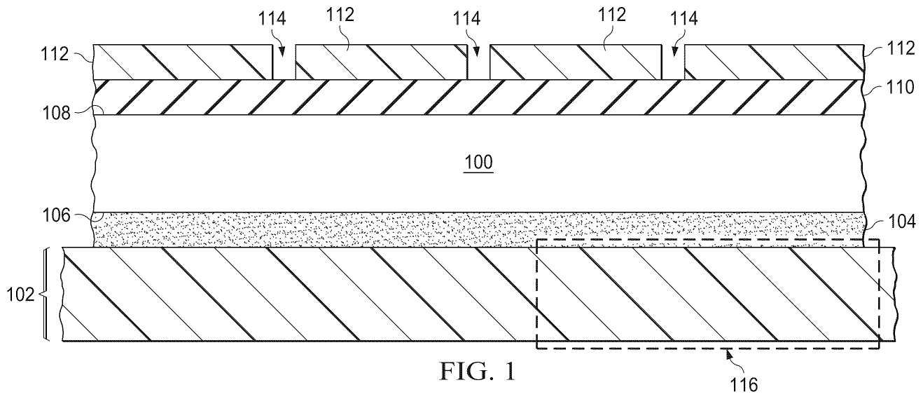

FIG. 1 is a cross-sectional view of a substrate affixed to a dicing tape according to one example. The substrate is a wafer 100 that is affixed to a dicing tape 102 by a die attach film 104. A plurality of semiconductor dies are formed on the wafer 100 according to respective fabrication processing steps. For example, each of the dies on the wafer 100 can contain any combination of active and passive devices, such as bipolar junction transistors, capacitors, optoelectronic devices, inductors, resistors, and diodes.

The wafer 100 has a first surface 106 opposite a second surface 108. The wafer 100 is mounted to the dicing tape 102 with the die attach film 104, such that the die attach film 104 is located between the first surface 106 of the wafer 100 and the dicing tape 102. The active devices and/or passive devices are formed with landing pads at the second surface 108. The dicing tape 102 includes a filler material and a nonconductive material.

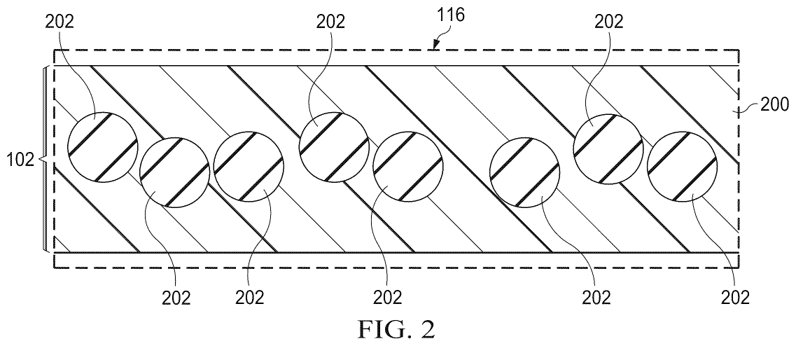

FIG. 2 is an expanded view of a region 116 of FIG. 1 that includes the structure of the dicing tape 102. Thus, FIGS. 1 and 2 employ the same reference numbers to denote the same features. The dicing tape 102 includes a filler material 200 and a nonconductive material 202. As shown in the example of FIG. 1, the nonconductive material 202 is suspended in the filler material 200. The filler material 200 is a thermoplastic resin, such as a natural rubber, copolymer, polybutadiene resin, polyimide resins, saturated polyether resins, phenoxy resins, acrylic resins, acrylates, etc. The thermoplastic resins are used alone or in combination to form the filler material 200.

The nonconductive material 202 is distributed to the filler material 200. The nonconductive material 202 includes a number of nonconductive particles. The nonconductive material 202 does not conduct electricity and is, for example, silicon dioxide, aluminum dioxide, zirconium dioxide, etc. The nonconductive particles of the nonconductive material 202 are interspersed throughout the filler material 200 of the dicing tape 102. The particle size of the nonconductive material 202 defines a diameter or length of the nonconductive particles of the nonconductive material. In one example, the particle size is 1 nanometer to 10 micrometers based on the thickness of the dicing tape 102. The particle size may approach the thickness of the dicing tape 102. For example, if the thickness of the dicing tape 102 is 10 micrometers, the particle size of the nonconductive material is approximately 9 micrometers. The particle density of the nonconductive material is 1%-50% by weight of the dicing tape 102.

Returning to FIG. 1, a passivation layer 110 is applied to the second surface 108 of the wafer 100 and acts as a protective overcoat that provides resistance to ions and contaminants. The passivation layer 110 is formed of an insulating material, for example, polysilicon, silicon oxynitride, polyimide, etc. A patterned photoresist layer 112 is applied to the passivation layer 110. The patterned photoresist layer 112 includes a number of voids 114. The voids 114 in the patterned photoresist layer 112 are positioned to correspond to boundaries between dies of the plurality of dies formed in the wafer 100. Accordingly, the passivation layer 110 can be etched at the voids 114 to form scribe lines in the passivation layer 110. During a singulation process, the wafer 100 is diced at the scribe lines to singulate the individual dies of the plurality of dies of the wafer 100.

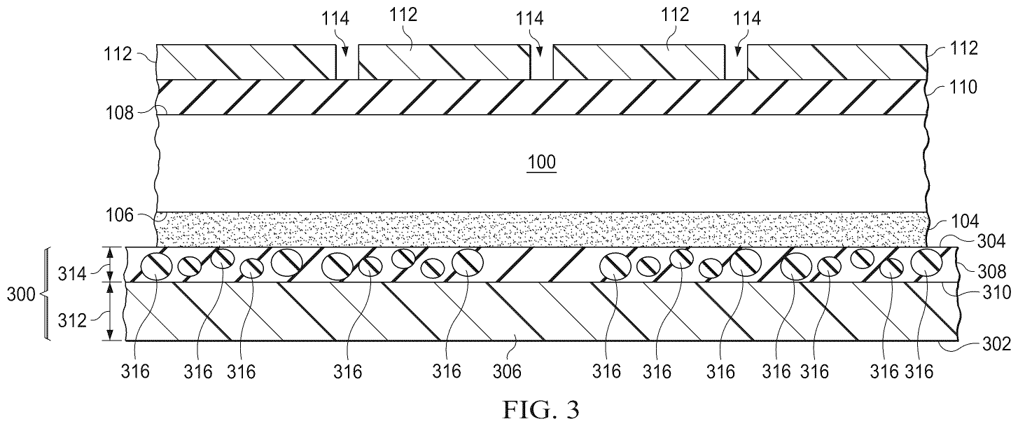

FIG. 3 is a cross-sectional view of a non-conductive material combined with an alternative example of a dicing tape. For purposes of simplification, FIGS. 1 and 3 employ the same reference numbers to denote the same structure.

The substrate is a wafer 100 that is affixed to a dicing tape 300 by a die attach film 104. The wafer 100 has a first surface 106 opposite a second surface 108. The die attach film 104 is mounted at the first surface 106 of the wafer 100. The wafer 100 is mounted to the dicing tape 300 with the die attach film 104, such that the die attach film 104 is located between the first surface 106 of the wafer 100 and the dicing tape 300.

The dicing tape 300 extends from a first tape surface 302 to a second tape surface 304. The dicing tape 300 is a multilayer structure having a base layer 306 and an etch stop layer 308. The base layer 306 extends from the first tape surface 302 to an interface surface 310 and has a base thickness 312 defined as the distance between the first tape surface 302 and the interface surface 310. The etch stop layer 308 extends from the interface surface 310 to the second tape surface 304 and has an etch stop thickness 314 defined as the distance between the interface surface 310 and the second tape surface 304. In some examples, the base thickness 312 is greater than the etch stop thickness 314.

The base layer 306 is formed of a filler material (e.g., the filler material 200 of FIG. 2), such as a thermoplastic resin. The etch stop layer 308 is formed of an adhesive material mixed with a number of nonconductive particles of a nonconductive material 316 (e.g., the nonconductive material 202 of FIG. 2). In some examples, the adhesive is the filler material of the base layer 306, such that the base layer 306 is formed of the filler material without the nonconductive material 316 and the etch stop layer 308 is formed of the filler material with the nonconductive material 316. Alternatively, the adhesive material is different than the filler material. The adhesive material, for example, is a thermosetting resin with high cohesive strength.

The etch stop layer 308 applied, for example, by a screen-printing process, dispensing process, or jetting process. The nonconductive material 316 does not conduct electricity and is, for example, silicon dioxide, aluminum dioxide, zirconium dioxide, etc. The particle size of the nonconductive material 316 is 1 nanometer to 10 micrometers based on the etch stop thickness 314 of the etch stop layer 308. The particle size may approach the etch stop thickness 314. For example, if the etch stop thickness 314 of the etch stop layer 308 is 10 nanometers, the particle size of the nonconductive material 316 is approximately 9 nanometers. The particle density of the nonconductive material 316 is 1%-50% by weight of the etch stop layer 308. Accordingly, the nonconductive material 316 is formed in the etch stop layer 308 at the second tape surface 304 of the dicing tape 300 in contact with the die attach film 104. Thus, the etch stop layer 308 acts as a barrier for the base layer 306.

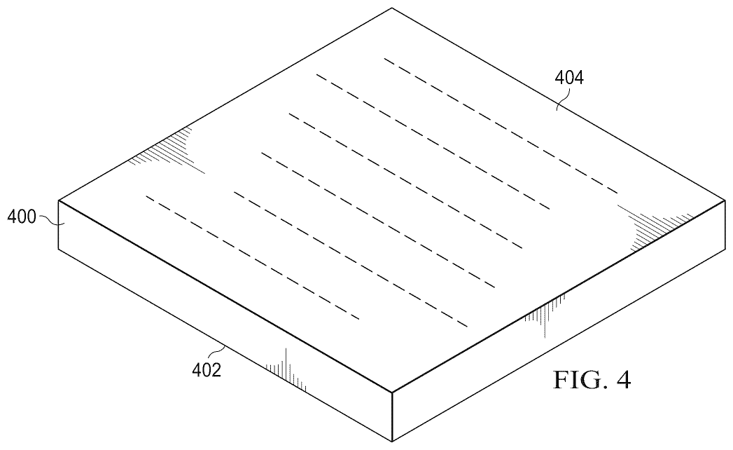

FIGS. 4-15 illustrate operations of a process flow for forming a semiconductor device. For purposes of simplification, FIGS. 4-15 employ the same reference numbers to denote the same structure.

FIG. 4 illustrates an example of a first stage of the process flow. A wafer 400 (e.g., the wafer 100 of FIG. 1) having a first surface 402 (e.g., the first surface 106 of FIG. 1) opposite a second surface 404 (e.g., the second surface 108 of FIG. 1) is provided in the first stage. The wafer 400 is a substrate, such as silicon, silicon carbide, or other suitable material, either in substantially pure form or in combination with additional materials. As another example, the wafer 400 is a single crystal material, such as a single crystal silicon substrate. As yet another example, the wafer 400 is a complementary metal-oxide semiconductor (CMOS) substrate and includes circuitry formed thereon. The wafer 400 includes a plurality of dies. The second surface 404 may include leads for circuitry formed on each of the respective dies of the plurality of dies. The formation of the wafer 400 is dependent on the application of the semiconductor device being fabricated.

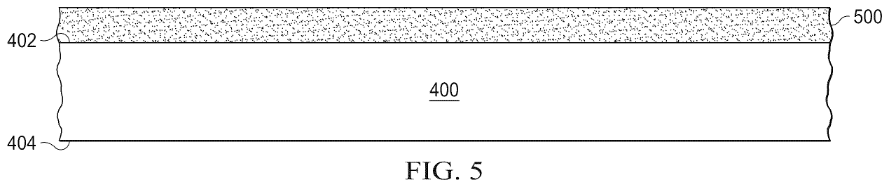

FIG. 5 illustrates an example of a second stage of the process flow. A die attach film 500 (e.g., the die attach film 104 of FIG. 1) is applied to the first surface 402 of the wafer 400. In another example, the die attach film 500 can be applied to the dicing tape. The die attach film 500 is a filmy adhesive agent, such as an epoxy resin.

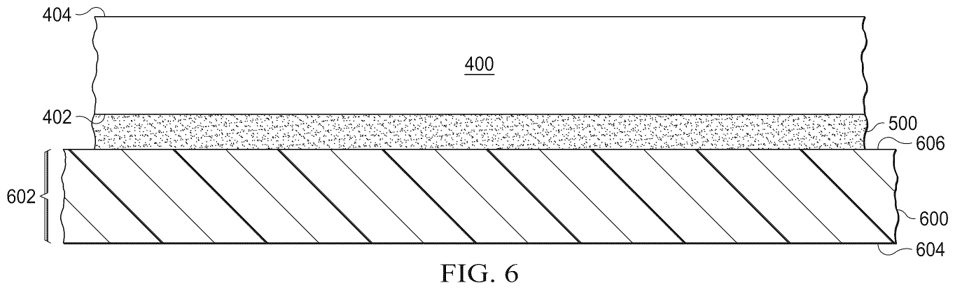

FIG. 6 illustrates an example of a third stage of a process flow. In the third stage, the wafer 400 is affixed to dicing tape 600 (e.g., the dicing tape 102 of FIG. 1, the dicing tape 300 of FIG. 3) using the die attach film 500. The die attach film 500 bonds the wafer 400 to the dicing tape 600 to support the dies during and after singulation. The dicing tape 600 has a thickness 602 defined between a first tape surface 604 (e.g., the first tape surface 302 of FIG. 3) and a second tape surface 606 (e.g., the second tape surface 304 of FIG. 3).

The dicing tape 600 may be a single layer structure of a filler material (e.g., the filler material 200 of FIG. 2) mixed with a nonconductive material (e.g., the nonconductive material 202 of FIG. 2, the nonconductive material 316 of FIG. 3) that is resistant to plasma etching. In the single structure example, the dicing tape 600 acts as an etch stop layer during plasma etching. In a multi-layer structure example, the dicing tape 600 includes a base layer (e.g., the base layer 306 of FIG. 3) and an etch stop layer (e.g., the etch stop layer 308 of FIG. 3) with a nonconductive material (e.g., the nonconductive material 202 of FIG. 2, the nonconductive material 316 of FIG. 3). During plasma etching, the etch stop layer of the dicing tape 600 acts as an etch stop. Therefore, in both the single structure example and the multi-layer structure example of the dicing tape 600, the nonconductive material is resistant to plasma etching and mitigates the deterioration of the dicing tape 600 during plasma etching.

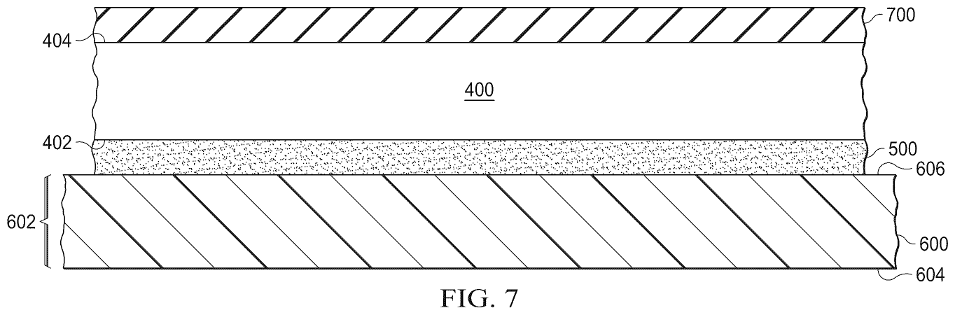

FIG. 7 illustrates an example of a fourth stage of the process flow. A passivation layer 700 (e.g., the passivation layer 110 of FIG. 1) is applied to the second surface 404 of the wafer 400 and acts as a protective overcoat for the wafer 400. The passivation layer 700 is deposited using any suitable deposition technique, such as Chemical Vapor Deposition (CVD). As some examples, the passivation layer 700 is an insulator. The passivation layer 700 is, for example, polysilicon, silicon nitride, silicon oxynitride, polyimide, etc.

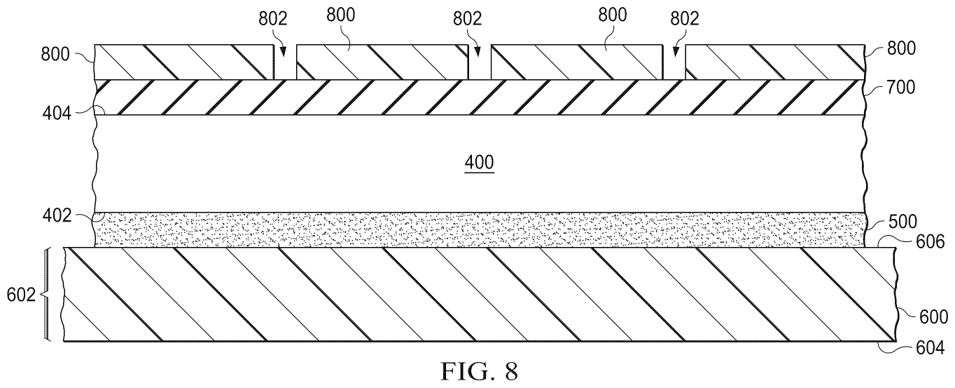

FIG. 8 illustrates an example of a fifth stage of the process flow. In the fifth stage, a photoresist layer 800 (e.g., the patterned photoresist layer 112 of FIG. 1) is formed on the passivation layer 700. The photoresist layer 800 is a light-sensitive material used in several processes, including photolithography, photoengraving, and photoresist etching that allow underlying layers to be patterned. The photoresist layer 800 includes voids 802 (e.g., the voids 114 of FIG. 1) for patterning of the passivation layer 700.

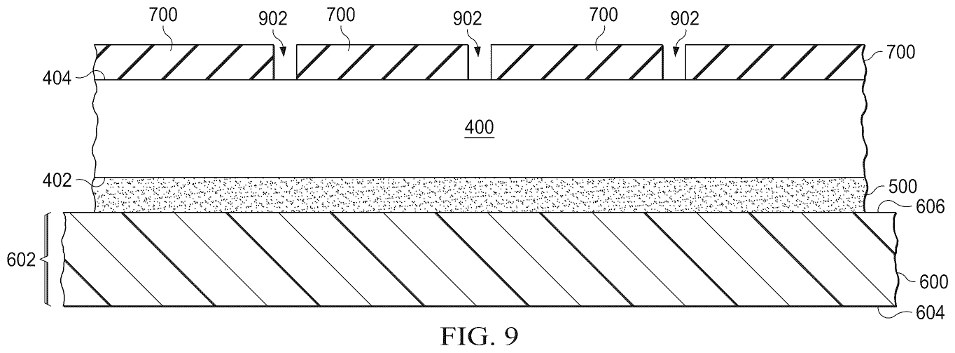

FIG. 9 illustrates an example of a sixth stage of the process flow. In the sixth stage, the passivation layer 700 is patterned by a performing selective irradiation and the photoresist layer 800 is removed from the patterned passivation layer 700. The irradiated or nonirradiated portions are removed by applying a developer material. For example, a dry etch is performed on the passivation layer 700 is to form the scribe lines 902 corresponding to the voids 802. The scribe lines 902 in the passivation layer 700 indicate individual dies of the plurality of dies in the wafer 400. Accordingly, the area of the wafer 400 that is overlayed by a scribe line 902 does not include circuit elements of the dies such that the dies can be singulated along the scribe lines 902.

FIG. 10 illustrates an example of a seventh stage of the process flow. In the seventh stage, the wafer 400 is plasma diced into a plurality of dies including a first die 1000, a second die 1002, a third die 1004, and fourth die 1006. The plasma dicing uses plasma etching techniques to singulate the dies 1000-1006. The dies 1000-1006 include material of the wafer 400 as well as material of the die attach film 500. In other examples, the dies 1000-1006 include material of the wafer 400.

The plasma etching techniques include placing the wafer 400 in a dicing chamber 1008. The dicing chamber 1008 may be a vacuum chamber fitted with a high-density plasma source such as inductively coupled plasma (ICP). A plasma is created in the dicing chamber 1008 by exciting ions in an etch gas having a gas chemistry based on the material of the wafer 400. For example, the etch gas includes a halogen (e.g., fluorine, chlorine, bromine, or iodine) or halogen-containing gas. In response to the reaction between the plasma and the portions of the wafer 400 exposed by the scribe lines 902, material of the wafer 400 and the underlying die attach film 500 are removed such that individual dies 1000-1006 are singulated from the wafer 400.

The plasma dicing may include performing a number of plasma etches using different gas chemistries. For example, a first plasma etch having a first gas chemistry is performed to remove portions of the wafer 400 and a second plasma etch having a second gas chemistry is performed to remove portions of the die attach film 500. Additionally, the passivation layer 700 may be removed from the second surface 404 of the wafer 400 during plasma dicing. Alternatively, the passivation layer 700 is removed prior to plasma dicing or after plasma dicing. The nonconductive material of the dicing tape 600 is resistant to etching such that dicing tape 600 is not severed during the plasma dicing. Because the singulation process does not sever the dicing tape 600, the dies 1000-1006 remain supported due to adhesion to the dicing tape 600.

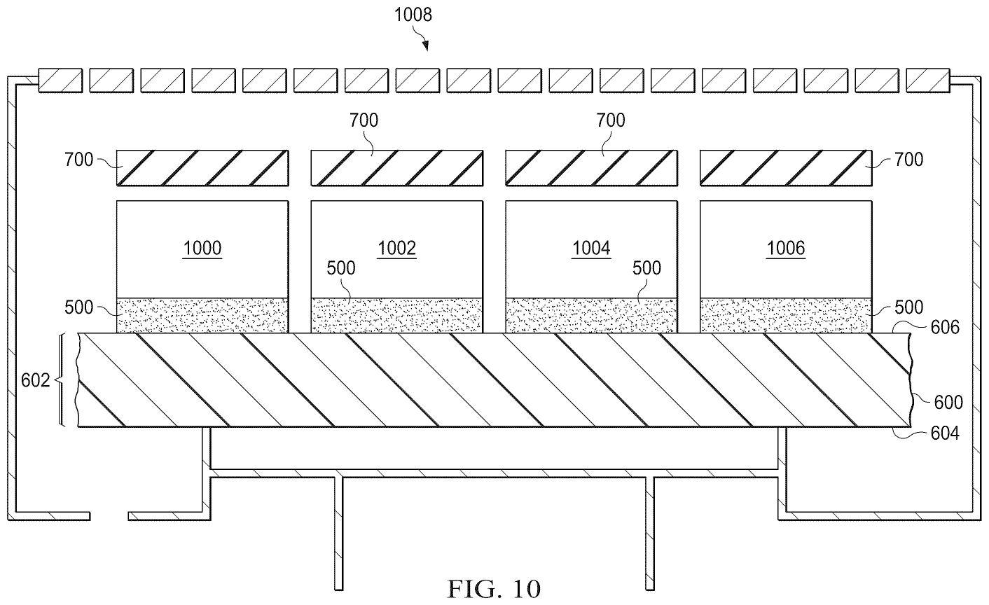

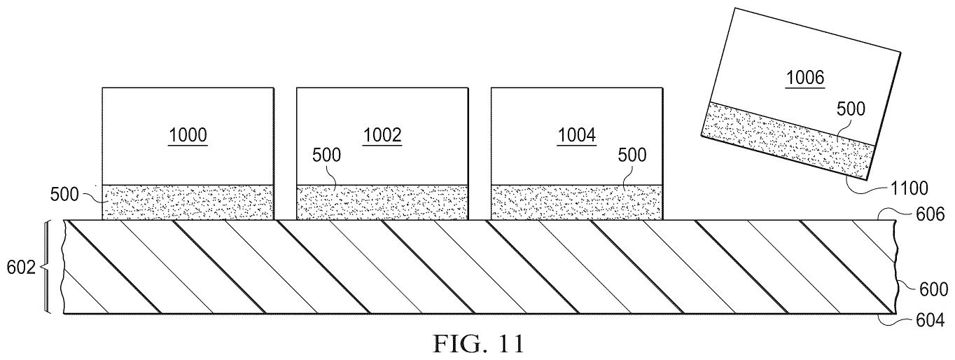

FIG. 11 illustrates an example of an eighth stage of the process flow. In the eighth stage, the individual dies are released from the dicing tape 600. For example, the fourth die 1006 is pushed from the dicing tape 600 with a pin. As another example, the dicing tape 600 is drawn away from the dies 1000-1006 by vacuum. Because the nonconductive material is incorporated with the dicing tape 600, is some examples, the nonconductive material is left as a residue on the dies 1000-1006 after the dies are released. In the example in which the nonconductive material is silicon dioxide, silicon dioxide particles may remain on a die attach surface 1100 of the die attach material from the die attach film 500. In another example, the first surface 402 of the wafer 400 is adhered on a face of the dicing tape 600 and particles of the nonconductive material remain on the corresponding second surface of the dies 1000-1006.

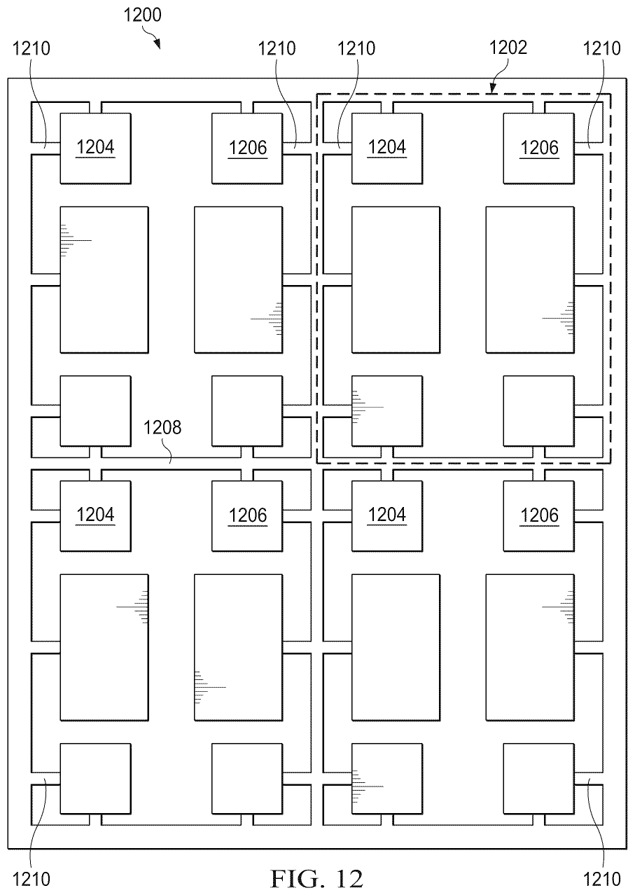

FIG. 12 illustrates an example of a ninth stage of the process flow. In the ninth stage, an interconnect 1200 is provided. The interconnect 1200 is formed of an electrically conductive material, such as copper, palladium, gold, silver, or other appropriate conductive metal or metal alloy with similar properties. For example, the interconnect is formed from a copper sheet. As one example, the interconnect 1200 accommodates four dies (e.g., the first die 1000, the second die 1002, the third die 1004, and the fourth die 1006 of FIG. 10). An interconnect area 1202 is configured to accommodate a single die.

For a chip on lead configuration of a semiconductor, the interconnect area 1202 has wire bond pads including a first wire bond pad 1204 and a second wire bond pad 1206 that are electrically isolated from each other. For other configurations of a semiconductor device, the interconnect 1200 may include a die attach pad directly under the die. The wire bond pads 1204, 1206 are typically connected to saw streets 1208 with tie bars 1210. The saw streets 1208 and the tie bars 1210 are formed of thin metal strips. The saw streets 1208 support the interconnect 1200 during die attach (IC chip attachment to the interconnect), wire bonding (wire connecting IC bond pads to wire bond pads), and potting (encapsulation of the IC chip, wire bonds, and interconnects 1200 with mold compound).

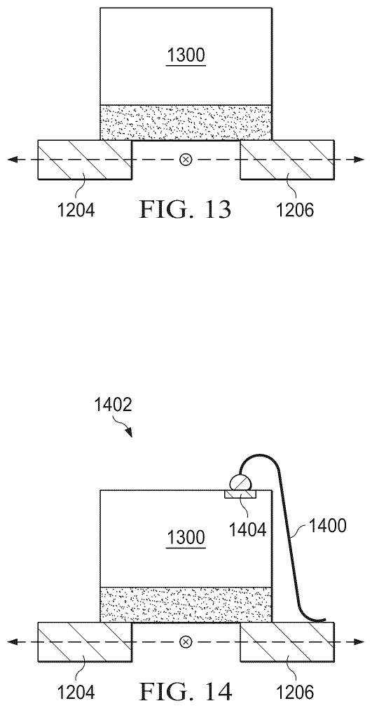

FIG. 13 illustrates an example of a tenth stage of the process flow. For clarity, the remaining stages will be shown and described with respect to a single die and a portion of the interconnect area 1202. In the tenth stage, a die 1300 (e.g., the first die 1000, the second die 1002, the third die 1004, the fourth die 1006 of FIG. 10) is mounted on the wire bond pads 1204, 1206. The die 1300 is mounted using the die attach material of the die attach film 500 or a bonding layer used to affix the die 1300 to the interconnect area 1202.

FIG. 14 illustrates an example of an eleventh stage of the process flow. In the eleventh stage, a bond wire 1400 is attached at the die 1300 and the wire bond pads 1204, 1206 resulting in a semiconductor device 1402. The bond wire 1400 forms an electrical connection between the die 1300, at a first landing pad 1404, and the second wire bond pad 1206.

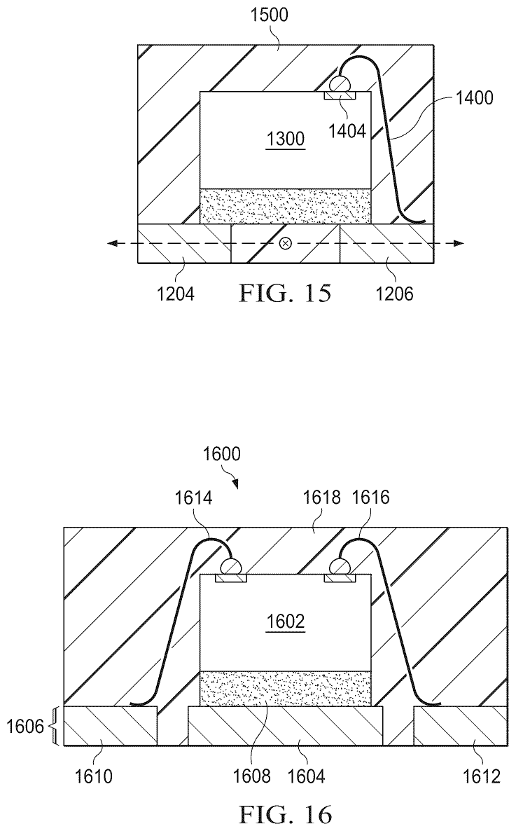

FIG. 15 illustrates an example of a twelfth stage of a process flow of fabricating a semiconductor device. In the twelfth stage, the semiconductor device 1402 is encapsulated in a mold compound 1500. The mold compound 1500 is formed of one or more insulating material, such as organic resins (e.g., epoxy), inorganic resins, and/or other suitable materials. The mold compound 1500 at least partially encapsulates the die 1300, the wire bond pads 1204, 1206, and the bond wire 1400.

FIG. 16 illustrates another example integrated circuit package fabricated using the dicing tape. As discussed above with respect to FIG. 12, a semiconductor device having a chip on lead configuration may be fabricated. In another example, an integrated circuit (IC) 1600 having a standard configuration is fabricated. For example, a singulated die 1602 (e.g., the first die 1000, the second die 1002, the third die 1004, the fourth die 1006 of FIG. 10, the die 1300 of FIG. 13) is mounted on a die attach pad 1604 of an interconnect 1606 (e.g., the interconnect 1200 of FIG. 12). The singulated die 1602 is affixed to the die attach pad 1604 with a die attach film 1608 (e.g., the die attach film 104 of FIG. 1, the die attach film 500 of FIG. 5). In some examples, the singulated die 1602 and/or the die attach film 1608 have a residue of nonconductive material (e.g., the nonconductive material 202 of FIG. 2, the nonconductive material 316 of FIG. 3) from a dicing tape (e.g., the dicing tape 102 of FIG. 1, the dicing tape 300 of FIG. 3, the dicing tape 600 of FIG. 6) that the singulated die 1602 was affixed to during fabrication.

The interconnect 1606 also includes a first wire bond pad 1610 (e.g., the first wire bond pad 1204 of FIG. 12) and a second wire bond pad 1612 (e.g., the second wire bond pad 1206 of FIG. 12). A first bond wire 1614 (e.g., the bond wire 1400) is attached at the singulated die 1602 and at a first wire bond pad 1610. A second bond wire 1616 (e.g., the bond wire 1400) is attached at the singulated die 1602 and at a second wire bond pad 1612. The die attach pad 1604, the first wire bond pad 1610, the second wire bond pad 1612, the first bond wire 1614, and the second bond wire 1616 are at least partially encapsulated in a mold compound 1618 (e.g., the mold compound 1500 of FIG. 15) to form the IC 1600.

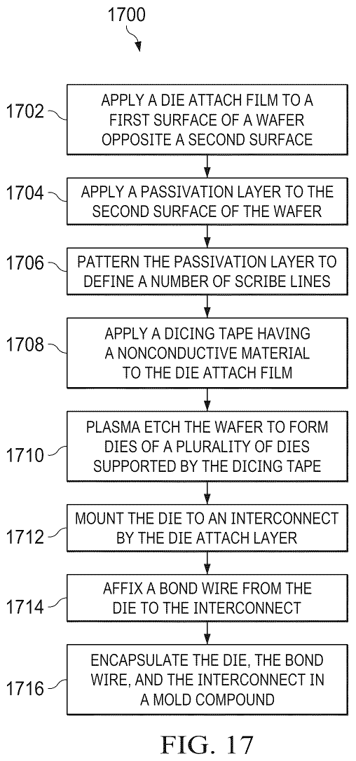

FIG. 17 illustrates a flowchart of an example method for fabricating semiconductor device. For simplicity, the method 1700 will be described as a sequence of blocks, but it is understood that the elements of the method 1700 can be organized into different architectures, elements, stages, and/or processes.

At block 1702, the method 1700 includes forming a die attach film (e.g., the die attach film 104 of FIG. 1, the die attach film 500 of FIG. 5) to a first surface (e.g., the first surface 106 of FIG. 1, the first surface 402 of FIG. 4) of a wafer (e.g., the wafer 100 of FIG. 1, the wafer 400 of FIG. 4) opposite a second surface (e.g., the second surface 108 of FIG. 1, the second surface 404 of FIG. 4).

At block 1704, the method 1700 includes applying a passivation layer (e.g., the passivation layer 700 of FIG. 7) to the second surface of the wafer.

At block 1706, the method 1700 includes patterning the passivation layer to define a number of scribe lines (e.g., the scribe lines 902 of FIG. 9). As one example, the passivation layer is patterned using a photoresist layer (e.g., the photoresist layer 800 of FIG. 8).

At block 1708, the method 1700 includes applying a dicing tape (e.g., the dicing tape 102 of FIG. 1, the dicing tape 300 of FIG. 3, the dicing tape 600 of FIG. 6) having a nonconductive material (e.g., the nonconductive material 202 of FIG. 2) to the die attach film. The nonconductive material is resistant to plasma etching. Specifically, the nonconductive material that acts as an etch stop. Accordingly, the nonconductive material mitigates damage to the dicing tape during plasma etching so that the dicing tape is not severed during singulation.

At block 1710, the method 1700 includes plasma etching the wafer to form dies of a plurality of dies (e.g., the first die 1000, the second die 1002, the third die 1004, the fourth die 1006 of FIG. 10, the die 1300 of FIG. 13, the die 1602 of FIG. 16) supported by the dicing tape. The plasma etching removes material of the wafer and die attach film exposed by the scribe lines.

At block 1712, the method 1700 includes mounting the die to an interconnect (e.g., the interconnect 1200 of FIG. 12, the interconnect 1606 of FIG. 16) by the die attach film remaining on the dies. In particular, the die is mounted an interconnect area (e.g., the interconnect area 1202 of FIG. 12) having bond pads (e.g., the first wire bond pad 1204, the second wire bond pad 1206 of FIG. 12) and/or a die attach pad (e.g., the die attach pad 1604 of FIG. 16). A portion of the nonconductive material may also remain on the dies leaving a nonconductive residue.

At block 1714, the method 1700 includes affixing a bond wire (e.g., a bond wire 1400 of FIG. 14, the first bond wire 1614 and the second bond wire 1616 of FIG. 16) from the die to the interconnect. For example, the bond wires electrically connect the die to a wire bond pad.

At block 1716, the method 1700 includes encapsulating the die, the bond wire, and the interconnect in a mold compound (e.g., the mold compound 1500 of FIG. 15, the mold compound 1618 of FIG. 16).

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising,” “comprises,” “including,” “includes,” or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations, or improvements therein may be subsequently made by those skilled in the art which are also intended to be encompassed by the following claims.

What is claimed is:

1. A method of forming an integrated circuit (IC) comprising:
forming a die attach film to a first surface of a wafer opposite a second surface;
applying a passivation layer to the second surface of the wafer;
patterning the passivation layer to define a number of scribe lines;
applying a dicing tape having a nonconductive material to the die attach film, wherein the nonconductive material is resistant to plasma etching; and
plasma etching the wafer to form dies of a plurality of dies supported by the dicing tape based on the scribe lines.

2. The method of claim 1, wherein the dicing tape is filled with the nonconductive material.

3. The method of claim 1, wherein the nonconductive material is formed in an etch stop layer at a surface of the dicing tape in contact with the die attach film.

4. The method of claim 3, wherein the etch stop layer is an adhesive.

5. The method of claim 1, wherein the nonconductive material is silicon dioxide or aluminum dioxide.

6. The method of claim 1, wherein a particle size of the nonconductive material is 1 nanometer to 10 micrometers based on a thickness of the dicing tape.

7. The method of claim 1, wherein a particle density of the nonconductive material is 1%-50% by weight of the dicing tape.

8. The method of claim 1, further comprising:
mounting the die to an interconnect by the die attach film;
affixing a bond wire from the die to the interconnect; and
encapsulating the die, the bond wire, and the interconnect in a mold compound.

9. A method of forming an integrated circuit (IC) comprising:
apply a die attach film to a first surface of a wafer opposite a second surface;
applying a passivation layer to the second surface of the wafer;
patterning the passivation layer to define a number of scribe lines;
applying a dicing tape having a nonconductive material to the die attach film, wherein the nonconductive material is resistant to plasma etching;
plasma etching the wafer to form dies of a plurality of dies supported by the dicing tape based on the scribe lines;
mounting the die to an interconnect by the die attach film;
affixing a bond wire from the die to the interconnect; and
encapsulating the die, the bond wire, and the interconnect in a mold compound.

10. The method of claim 9, wherein the dicing tape is a single layer filled with the nonconductive material.

11. The method of claim 9, wherein the dicing tape includes a base layer and an etch stop layer including the nonconductive material, wherein the etch stop layer is at a surface of the dicing tape in contact with the die attach film.

12. The method of claim 11, wherein the etch stop layer is an adhesive.

13. The method of claim 9, wherein the nonconductive material is silicon dioxide or aluminum dioxide.

14. The method of claim 9, wherein a particle size of the nonconductive material is 1 nanometer to 10 micrometers.

15. The method of claim 9, wherein a particle density of the nonconductive material is 1%-50% by weight of the dicing tape.

16. A dicing tape for semiconductor processing, comprising:
a filler material; and
a nonconductive material, wherein the nonconductive material is silicon dioxide and is resistant to plasma etching, wherein the silicon dioxide has a particle size of 1 nanometer to 10 micrometers based on a thickness of the dicing tape.

17. The dicing tape of claim 16, wherein the dicing tape is a single layer filled with the nonconductive material.

18. The dicing tape of claim 16, wherein the dicing tape includes a base layer and an etch stop layer including the nonconductive material, wherein the etch stop layer is at a surface of the dicing tape.

19. The dicing tape of claim 16, wherein the dicing tape includes a base layer that extends from a first tape surface to an interface surface, the base layer having a base thickness, and an etch stop layer that extends from the interface surface to a second tape surface, the etch stop layer having an etch stop thickness, and wherein the base thickness is greater than the etch stop thickness.

20. The dicing tape of claim 19, wherein the particle size is based on the etch stop thickness of the etch stop layer.
